(19) United States
(12) Patent Application Publication
(10) Pub. No.: US 2026/0100578 A1
(43) Pub. Date: Apr. 9, 2026

(54) POWER OUTAGE DETERMINATION DEVICE

(71) Applicants: Tractian Technologies Inc, Atlanta, GA (US); Tractian Limited, São Paulo (BR)

(72) Inventors: Henry Shinji Suzukawa, São Paulo (BR); Willian Loschner, São Paulo (BR); Vinicius Oliveira Romano Silva, São Paulo (BR); Igor Vinicius Alvarenga Marinelli, Atlanta, GA (US); João Pedro de Carvalho Voltani, São Paulo (BR)

(21) Appl. No.: 19/354,679

(22) Filed: Oct. 9, 2025

Related U.S. Application Data
(60) Provisional application No. 63/705,451, filed on Oct. 9, 2024.

(51) Int. Cl. H02J 3/0012; G01R 19/165

(52) U.S. Cl. CPC H02J 3/0012; G01R 19/16576

(57) ABSTRACT

Various embodiments are directed to a power outage determination device initiates an instance of an outage time range requirement based upon the power outage determination device detecting a first voltage value of the power outage determination device below an outage voltage value threshold. The power outage determination device monitors, during the instance of an outage time range requirement, whether the voltage of the power outage determination device (i) stays below or (ii) returns above the outage voltage value threshold. The power outage determination device detects an occurrence of a power outage event based upon the voltage staying below the outage voltage value threshold during an entirety of the instance of the outage time range requirement.

### CROSS-REFERENCE TO RELATED APPLICATIONS

This application claims the benefit of priority to U.S. Provisional Application No. 63/705,451, filed on Oct. 9, 2024, which is hereby incorporated by reference in its entirety.

### FIELD OF INVENTION

Various embodiments relate generally to sensing devices, and more particularly a sensing device used to determine power outages.

### SUMMARY

The appended claims may serve as a summary of this application. Various embodiments described herein provide improvements to conventional power loss detection circuits and related systems.

According to various embodiments, a power outage determination device initiates an instance of an outage time range requirement based upon the power outage determination device detecting a first voltage value of the power outage determination device below an outage voltage value threshold. The power outage determination device monitors, during the instance of an outage time range requirement, whether the voltage of the power outage determination device (i) stays below or (ii) returns above the outage voltage value threshold.

According to various embodiments, the power outage determination device detects an occurrence of power outage of a monitored power source. In some embodiments, the power outage determination device detects power outage from an electric grid, an AC electric circuit, A/C powered equipment, etc.

According to various embodiments, the power outage determination device detects an occurrence of a power outage event based upon subsequent detected voltage values staying below the outage voltage value threshold during an entirety of the instance of the outage time range requirement.

According to various embodiments, the power outage determination device is connected to, and continuously monitoring an operational status of, electrically powered equipment (such as industrial manufacturing equipment, motors, pumps, compressors, etc.). The power outage determination device and the electrically powered equipment may both receive power from the same power source. Electrically powered equipment may be, for example, any machine generally rotating-that performs mechanical work. Such mechanical work results from a transformation of received energy, which may be electrical, thermal or mechanical. Electrically powered equipment may be, but are not limited to, electric motors, hydraulic pumps, compressors, fans, generators and turbines. The power outage determination device generates operational data comprising vibration data representing motion patterns resulting from operation of the electrically powered equipment.

According to various embodiments, upon the power outage determination device detecting an occurrence of a power outage event, the power outage determination device generates data indicating a power outage occurring at the electrically powered equipment.

According to various embodiments, upon the power outage determination device detecting one or more subsequent voltage values returning above the outage voltage value threshold before termination of the instance of the outage time range requirement, the power outage determination device monitors whether further subsequent voltage values stay above the outage voltage value threshold during an instance of an interruption time range requirement. The power outage determination device initiates the instance of the interruption time range requirement initiated at a time the voltage initially returns above the outage voltage value threshold.

According to various embodiments, the power outage determination device detects an occurrence of an interruption event based upon the further subsequent voltage values staying above the outage voltage value threshold during an entirety of the instance of the interruption time range requirement.

These and other advantages of the present disclosure will be apparent to those of ordinary skill in the art by reference to the following Detailed Description and the accompanying drawings.

### BRIEF DESCRIPTION OF THE DRAWINGS

The present invention relates generally to a power outage detection circuit that includes a power outage determination device and capacitor that enables operation of the power outage determination device during a power outage.

The present disclosure will become better understood from the detailed description and the drawings, wherein:

FIG. 1A illustrates an example voltage outage event measured by a voltage power outage determination device over time according to example embodiments;

FIG. 1B illustrates an example timeline demonstrating a timestamp measurement and correction process according to example embodiments;

FIG. 2 illustrates an example electrical circuit configuration including a capacitor used to provide power to a power outage determination device during a power outage event according to example embodiments;

FIG. 3 illustrates an example network configuration including a power outage determination device reporting a voltage outage according to example embodiments;

FIG. 4A illustrates an example process of the voltage power outage determination device operation according to example embodiments;

FIG. 4B illustrates an example process of the voltage power outage determination device operation according to example embodiments; and

FIG. 5 is a diagram illustrating an exemplary computer that may perform processing in some embodiments.

### DETAILED DESCRIPTION

It will be readily understood that the instant components, as generally described and illustrated in the figures herein, may be arranged and designed in a wide variety of different configurations. Thus, the following detailed description of the embodiments of at least one of a method, apparatus, computer readable storage medium and system, as represented in the attached figures, is not intended to limit the scope of the application as claimed but is merely representative of selected embodiments. Multiple embodiments depicted herein are not intended to limit the scope of the solution. The computer-readable storage medium may be a non-transitory computer readable media or a non-transitory computer readable storage medium.

The instant features, structures, or characteristics described in this specification may be combined in any suitable manner in one or more embodiments. For example, the usage of the phrases “example embodiments,” “some embodiments,” or other similar language, throughout this specification refers to the fact that a particular feature, structure, or characteristic described in connection with the embodiment may be included in at least one example. Thus, appearances of the phrases “example embodiments”, “in some embodiments”, “in other embodiments,” or other similar language, throughout this specification can all refer to the same embodiment. Thus, these embodiments may work in conjunction with any of the other embodiments, may not be functionally separate, and the described features, structures, or characteristics may be combined in any suitable manner in one or more embodiments.

Example embodiments provide methods, systems, hardware components, non-transitory computer readable media, devices, and/or networks, which provide power outage detection. In one example, when the voltage drops below a certain voltage threshold (Vt), and also in the case when the power supply returns to a particular expected voltage operation level (Ve), the power outage determination device may trigger an alert that is sent via Wi-Fi, cellular, or via another communication medium to a computer device, such as a user device (e.g., laptop, computer, mobile device, smartphone, etc.).

In various embodiments, power outage detection may be performed to alert interested parties about a current power situation at a particular site and for a particular asset (device, system, machine etc.). In general, power fluctuations (outages, brief losses of power, etc.) may be identified by a voltage and/or current power outage determination device that is in contact with one or more conduits providing such power to the particular asset (“asset”), such as electrically powered equipment.

In various embodiments, the power cycles of an asset may vary and receiving an alert would be ideal especially when false positives can be avoided during the alert process. Power fluctuations which do not include voltage drops below a certain voltage level and/or for a certain period of time should be ignored while others which do violate those thresholds and time frames should be reported. Providing power to an alerting device such as a voltage, current and/or related energy power outage determination device may be a concern when power drops as those devices would require a separate power source, such as a battery or other power element, to maintain operation in the event of a power outage.

In one example, when the voltage drops below a certain voltage threshold (Vt), and also when the power supply returns to a particular expected operation level (Ve), the power outage determination device may trigger an alert that is sent to a computer device, such as a server and/or a user device (e.g., laptop, computer, mobile device, smartphone, etc.). During a power outage event related to a particular asset (e.g., computer, device, etc.), the power outage determination device would normally be powered down. However, according to example embodiments, a capacitor circuit element may be used with the power outage determination device to maintain operation of the power outage determination device for a definite period of time, (e.g., 10, 20, 30 seconds or more). By introducing a temporary power supply source, such as a capacitor in connection with the power outage determination device may still be available to initiate an alert during a power outage event.

In some embodiments, the power outage determination device does not have an onboard power source other than the capacitor circuit. For example, in some manufacturing environments, monitoring devices may not include batteries. In some embodiments, the power outage determination device will not use batteries as a backup power source, and instead use the capacitor circuit to provide power to the power outage determination device until the power is restored or until the charge of the capacitor circuit is exhausted.

An outage detection algorithm may detect power fluctuations and may be responsible for differentiating the power fluctuations (short term power loss) from an actual power outage event (longer term power loss). The algorithm may use a variation of the root mean square (RMS) of the voltage measured as a function of time and detect a power outage when the RMS value drops below a certain threshold. Before triggering an outage event, the algorithm used is setup to determine that the voltage will not return to its ‘expected’ or ‘nominal’ value within a configured period. After that, an outage is triggered.

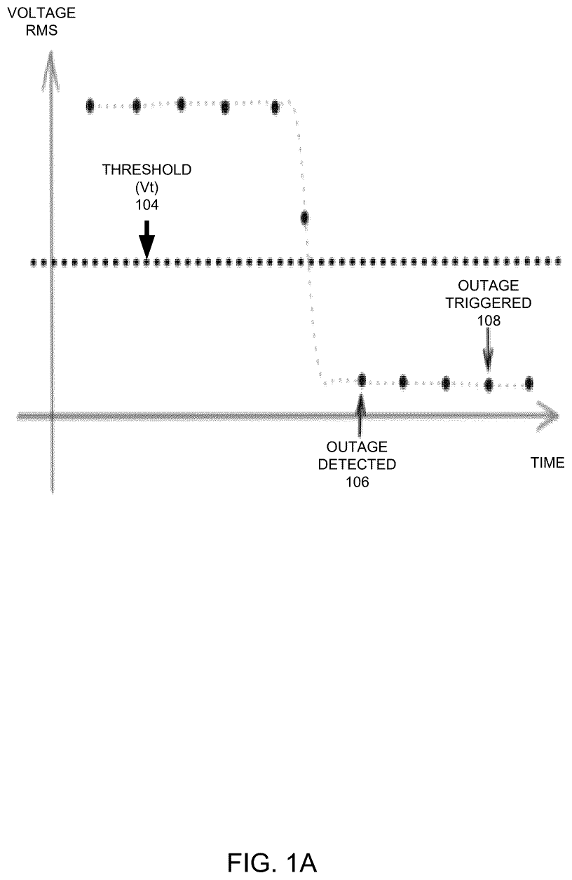

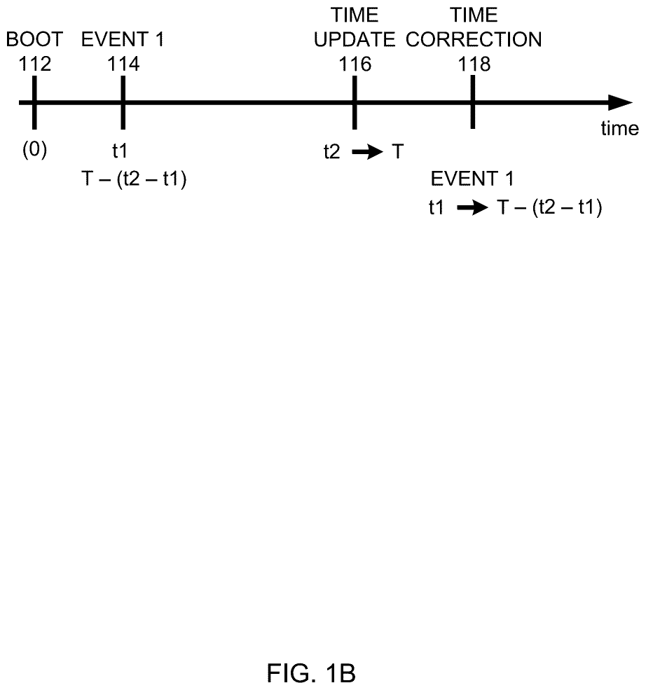

FIG. 1A illustrates an example voltage outage event measured by a voltage power outage determination device over time according to example embodiments. Referring to FIG. 1A, the example graph demonstrates the calculations of various voltage RMS values which may be updated each half cycle of the fundamental voltage frequency. In one example, each RMS point will be calculated using 12 cycles of the fundamental voltage frequency. The dotted center line 104 may be considered a voltage threshold (Vt) that when a measured RMS value drops below the value Vt, then a power outage event may be considered active by the power outage determination device. An initial outage determination may be made 106 when the voltage Vt is identified at a particular RMS point below the voltage threshold Vt. The time requirement established by the power outage determination device and the corresponding outage algorithm may not attempt to trigger an outage notification 108 until a number of RMS calculation cycles have passed. The period of time prior to reporting the outage may be a way to reduce false positive notifications when the power outage is only brief or temporary and may not require action by interested parties.

One skilled in the art may appreciate any value of voltage being considered a Vt value depending on the application used for selection of such a voltage value. However, for purposes of this example, the voltage value may be 70 volts. An event trigger period (ETP) may be defined as the number of half cycles that the power outage determination device must be in an outage state (below Vt) for the algorithm to trigger an alert. A default value for the ETP may be 50. The ETP may be the point 108 on the graph where the notification is sent from the power outage determination device to the Internet via a wireless Wi-Fi, cellular or other communication medium.

After the outage event has occurred, the power outage determination device may be powered back on with the asset receiving additional power. A power recovery detection algorithm is responsible for differentiating a wake-up caused by a power outage from a wake-up caused by other sources (software resets, hardware resets, etc). Information may be obtained from the power outage determination device peripherals and the persisted data of the power outage algorithm. If enough data indicates a power recovery, a power recovery alert may be triggered.

FIG. 1B illustrates an example timeline demonstrating a timestamp measurement and correction process according to example embodiments. Referring to FIG. 1B, in one example, upon a boot operation 112, the power outage determination device will not have a correct timestamp to use when performing an alert. If an alert is issued before the power outage determination device's time correction procedure, an “alert placeholder” (event 1) 114 may be created using a “time since boot” variable T at time t1. As soon as the timestamp is known, all “alert placeholder” times are corrected taking out the difference between the current “time since boot” T and the placeholder's “time since boot” (t2−t1) from the current time. The time update value t2 will be updated 116 for T which will be substituted as the time correction 118 for event 1.

In one example, after the power outage determination device recovers power, it could lose its power source again before acquiring an internet connection to send the event trigger to interested parties. Because of such cases, the power events are persisted right after their creation in an event queue which may be stored in a memory associated with the power outage determination device or at a remote storage location. Upon receiving an Internet connection or reconnection, the events are sent in the order of their creation. The event queue persists the events on the power outage determination device's flash memory which could store information for a number of events (i.e., 20 events, etc.). Event placeholders are persisted with a timestamp zero, which is corrected when the time correction procedure initiates.

During the outage event, the power outage determination device may be powered down. This means that information on the period of the outage event may not be shared. For example, fluctuations in the voltage during the outage period and other detectable events. When a power outage determination device does not have power it may not be able to send the power outage alert at the start of the outage event. Also, events that are identified might be sent without a proper timestamp, as they might be created before acquiring the correct timestamp and sent after another outage event.

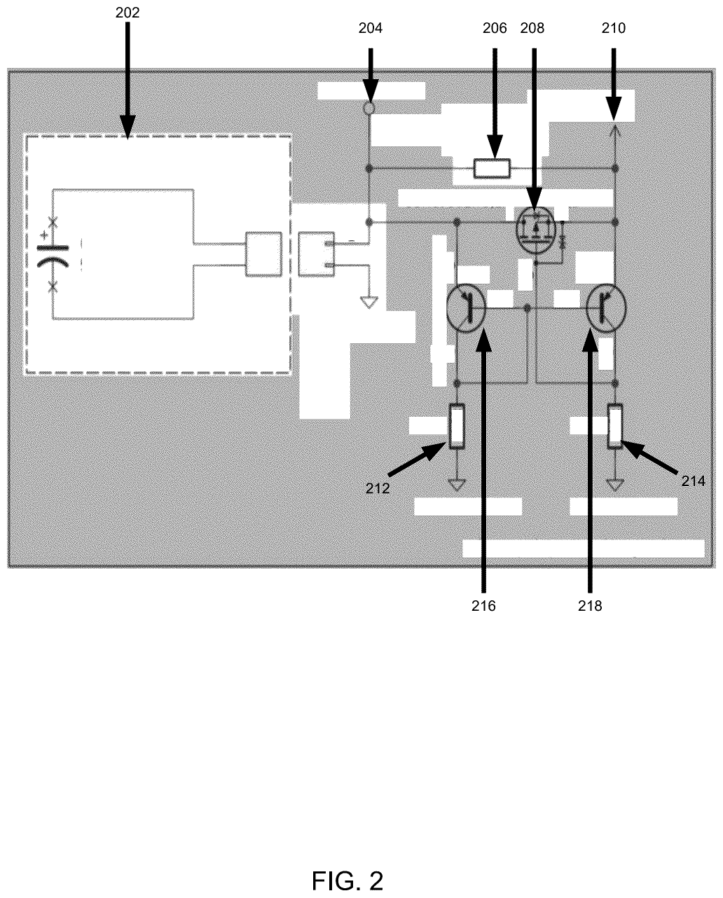

FIG. 2 illustrates an example electrical circuit configuration including a capacitor used to provide power to a power outage determination device during a power outage event according to example embodiments. Referring to FIG. 2, the circuit configuration includes a wire mounted capacitor and a charger circuit. The capacitor 202 may be a supercapacitor that is added to the main power line which may operate at 5 volts direct current (VDC). A high capacitance capacitor may discharge and appear as a short circuit to a power supply line. A resistor 206 may be added in series with the capacitance voltage (VCAP) to limit the charging current, which may take approximately eight minutes for the capacitor voltage 204 to reach its nominal voltage. The resistor 206 may limit current delivery to the entire circuit during a power outage. A diode may assist by providing a forward voltage drop to reduce the total operating time as a brownout voltage or temporary voltage drop would be obtained in a faster period of time. To resolve this issue, a MOSFET transistor or similar element 208 could be used to perform biasing. As a result, the voltage drop would be less than 400 mV. A power source of 5 volts 210 may be provided to the transistor 208 along with two bipolar junction transistors (BJTs) 216 and 218. The grounds may be connected via a pair of resistors 212 and 214.

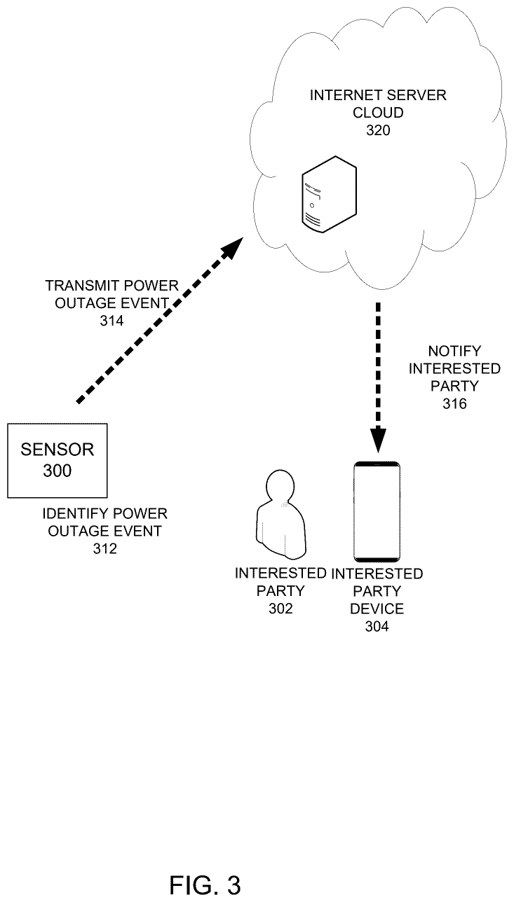

FIG. 3 illustrates an example network configuration including a power outage determination device reporting a voltage outage according to example embodiments. Referring to FIG. 3, the network diagram illustrates the power outage determination device 300 identifying a power outage event 312, such as a drop in power on a power line where the power outage determination device is disposed. When the power outage event qualifies as a valid power loss event, the event will be logged in a queue memory of the chip and/or transmitted to a remote network, such as a cellular network via a cellular communication device or chip in connection with the power outage determination device 300. The cloud network 320 may include one or more servers configured to receive and forward the alerts to interested parties that are registered to receive the alerts. In this example, a smartphone 304 of a user 302 may receive the alert 316.

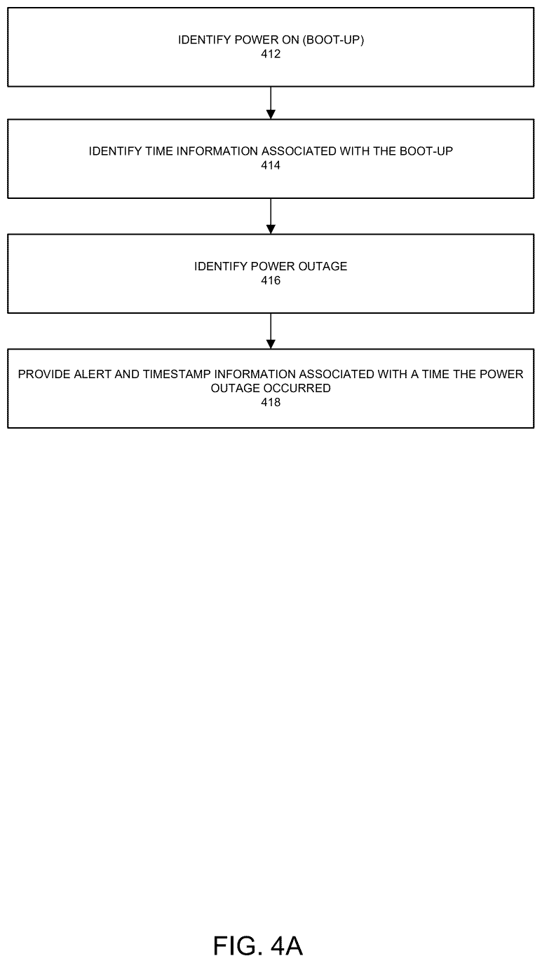

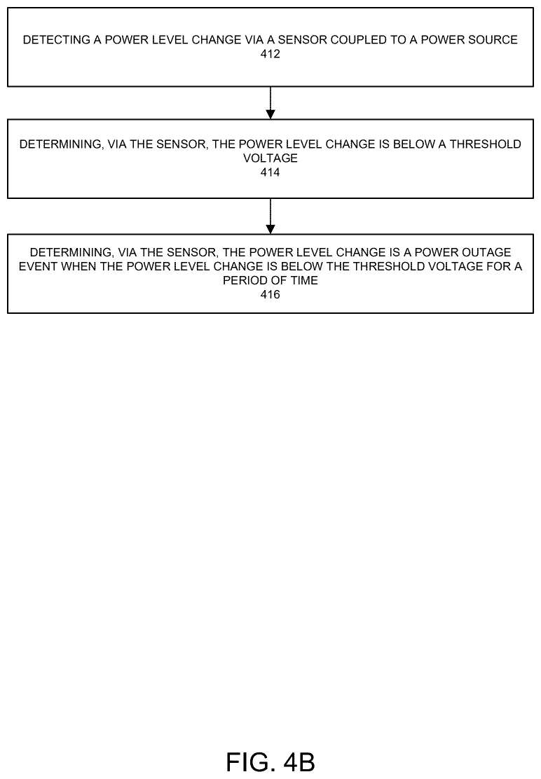

FIG. 4A illustrates an example process of the voltage power outage determination device operation according to example embodiments. Referring to FIG. 4A, the process may include identifying a power-up cycle (boot-up cycle) 412. The power outage determination device may receive power and attempt to transmit a notification/alert indicating it has received power and is booting up 414. The power outage determination device may use a timestamp that is temporary, such as a placeholder to establish time information since boot-up, however, that placeholder timestamp may later be replaced when a current time is identified by subtracting the time since boot-up from the updated time information in a time correction operation. A subsequent power outage may be identified by a voltage drop identified by the power outage determination device below a certain threshold voltage (Vt) 416 and an alert may be created that includes the timestamp information associated with a time the power outage occurred 418. The power outage determination device provides event information and time information paired with each power outage event identified.

FIG. 4B illustrates an example process of the voltage power outage determination device operation according to example embodiments. Referring to FIG. 4B, the process may include detecting a power level change via a power outage determination device coupled to a power source 412, determining, via the power outage determination device, the power level change is below a threshold voltage (Vt) 414 and determining, via the power outage determination device, the power level change is a power outage event when the power level change is below the threshold voltage for a period of time 416.

The method may include determining a root means square (RMS) value for the power source each half cycle of a fundamental voltage frequency, and when a number of half cycles identified as being below the threshold voltage has reached a threshold half cycle value, an alert is transmitted notifying of the power outage event. The threshold voltage is 70 volts and the threshold half cycle value is 50 in one example. Those skilled in the art will appreciate that those values could be modified depending on the type of voltage being monitored and the application being implemented. The power outage determination device may include a memory storing a queue of a plurality of power outage events. The power outage determination device may be coupled to a capacitor charging circuit which provides stored power to the power outage determination device for a period of time after the power outage event has occurred.

The process may also include powering the power outage determination device in a boot cycle after the power outage event, and issuing an alert placeholder comprising a placeholder time since boot value, via the power outage determination device, indicating that the power has been restored, identifying, via the power outage determination device, a timestamp value based on a current time, and correcting the alert placeholder by subtracting the difference between a current time since boot value and the placeholder time since boot value from the current time.

One skilled in the art will appreciate that a “system” could be embodied as a personal computer, a server, a console, a personal digital assistant (PDA), a cell phone, a tablet computing device, a smartphone or any other suitable computing device, or combination of devices. Presenting the above-described functions as being performed by a “system” is not intended to limit the scope of the present application in any way but is intended to provide one example of many embodiments. Indeed, methods, systems and apparatuses disclosed herein may be implemented in localized and distributed forms consistent with computing technology.

In this specification, reference is made in detail to specific embodiments of the invention. Some of the embodiments or their aspects are illustrated in the drawings.

For clarity in explanation, the invention has been described with reference to specific embodiments, however it should be understood that the invention is not limited to the described embodiments. On the contrary, the invention covers alternatives, modifications, and equivalents as may be included within its scope as defined by any patent claims. The following embodiments of the invention are set forth without any loss of generality to, and without imposing limitations on, the claimed invention. In the following description, specific details are set forth in order to provide a thorough understanding of the present invention. The present invention may be practiced without some or all of these specific details. In addition, well known features may not have been described in detail to avoid unnecessarily obscuring the invention.

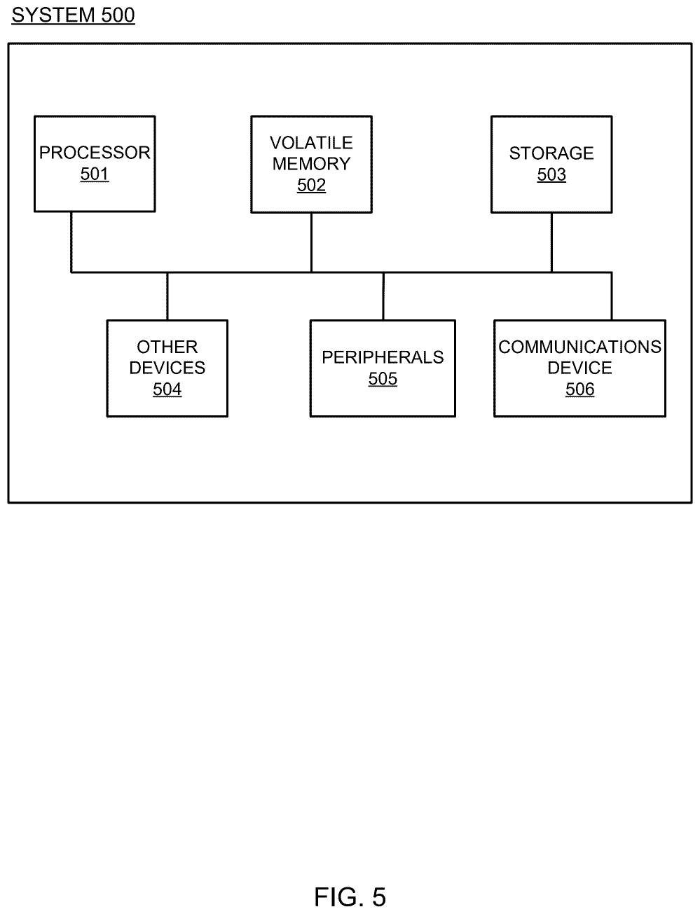

FIG. 5 is a diagram illustrating an exemplary computer that may perform processing in some embodiments. Exemplary computer 500 may perform operations consistent with some embodiments. The architecture of computer 500 is exemplary. Computers can be implemented in a variety of other ways. A wide variety of computers can be used in accordance with the embodiments herein.

Processor 501 may perform computing functions such as running computer programs. The volatile memory 502 may provide temporary storage of data for the processor 501. RAM is one kind of volatile memory. Volatile memory typically requires power to maintain its stored information. Storage 503 provides computer storage for data, instructions, and/or arbitrary information. Non-volatile memory, which can preserve data even when not powered and including disks and flash memory, is an example of storage. Storage 503 may be organized as a file system, database, or in other ways. Data, instructions, and information may be loaded from storage 503 into volatile memory 502 for processing by the processor 501.

The computer 500 may include peripherals 505. Peripherals 505 may include input peripherals such as a keyboard, mouse, trackball, video camera, microphone, and other input devices. Peripherals 505 may also include output devices such as a display. Peripherals 505 may include removable media devices such as CD-R and DVD-R recorders/players. Communications device 506 may connect the computer 100 to an external medium. For example, communications device 506 may take the form of a network adapter that provides communications to a network. A computer 500 may also include a variety of other devices 504. The various components of the computer 500 may be connected by a connection medium such as a bus, crossbar, or network.

It will be appreciated that the present disclosure may include any one and up to all of the following examples.

Example 1. A method comprising: initiating, by a power outage determination device, an instance of an outage time range requirement based upon the power outage determination device detecting a first voltage value of the power outage determination device below an outage voltage value threshold; monitoring during the instance of an outage time range requirement, by the power outage determination device, whether the voltage of the power outage determination device (i) stays below or (ii) returns above the outage voltage value threshold; and detecting, by the power outage determination device, an occurrence of a power outage event based upon the voltage staying below the outage voltage value threshold during an entirety of the instance of the outage time range requirement.

Example 2. The method of Example 1, comprising upon the power outage determination device detecting the voltage returning above the outage voltage value threshold before termination of the instance of the outage time range requirement: monitoring, by the power outage determination device, whether the voltage stays above the outage voltage value threshold during an instance of an interruption time range requirement, the instance of the interruption time range requirement initiated at a time the voltage initially returns above the outage voltage value threshold; and detecting, by the power outage determination device, an occurrence of an interruption event based upon the voltage of the power outage determination device staying above the outage voltage value threshold during an entirety of the instance of the interruption time range requirement.

Example 3. The method of any one of Examples 1-2, wherein the power outage determination device is connected to, and monitoring an operational status of, electrically powered equipment; and wherein the power outage determination device and the electrically powered equipment both receive power from a same power source.

Example 4. The method of one of Examples 1-3, wherein detecting an occurrence of a power outage event comprises: generating data, by the power outage determination device, indicating a power outage occurring at the electrically powered equipment.

Example 5. The method of one of Examples 1-4, wherein the power outage determination device is coupled to a capacitor charging circuit; and wherein detecting whether the voltage below the outage voltage value threshold comprises: drawing power from the capacitor, by the power outage determination device, during the instance of the outage time range requirement.

Example 6. The method of one of Examples 1-5, further comprising: initiating, by the power outage determination device, a power saving operational mode for the power outage determination device during the instance of the outage time range requirement.

Example 7. The method of one of Examples 1-6, further comprising: powering the power outage determination device in a boot cycle after the power outage event; and issuing an alert placeholder comprising a placeholder time since boot value, via the power outage determination device, indicating that the power has been restored.

Example 8. The method of one of Examples 1-7, further comprising: identifying, via the power outage determination device, a timestamp value based on a current time; and correcting the alert placeholder by subtracting a difference between a current time since boot value and the placeholder time since boot value from the current time.

Example 9. A power outage determination device comprising: a processor of the power outage determination device adapted to perform operations of: initiating an instance of an outage time range requirement based upon detecting a first voltage value of the power outage determination device below an outage voltage value threshold; monitoring during the instance of an outage time range requirement whether the voltage of the power outage determination device (i) stays below or (ii) returns above the outage voltage value threshold; and detecting an occurrence of a power outage event based upon the voltage staying below the outage voltage value threshold during an entirety of the instance of the outage time range requirement.

Example 10. The device of Example 9, further comprising: upon detecting the voltage returning above the outage voltage value threshold before termination of the instance of the outage time range requirement: monitoring whether the voltage stays above the outage voltage value threshold during an instance of an interruption time range requirement, the instance of the interruption time range requirement initiated at a time the voltage initially returns above the outage voltage value threshold; and detecting an occurrence of an interruption event based upon the voltage of the power outage determination device staying above the outage voltage value threshold during an entirety of the instance of the interruption time range requirement.

Example 11. The device of any one of Examples 9-10, wherein the power outage determination device is connected to, and monitors an operational status of, electrically powered equipment; and wherein the power outage determination device and the electrically powered equipment both receive power from a same power source.

Example 12. The device of any one of Examples 9-11, wherein detecting an occurrence of a power outage event comprises: generating data indicating a power outage occurring at the electrically powered equipment.

Example 13. The device of any one of Examples 9-12, wherein the power outage determination device is coupled to a capacitor charging circuit; and wherein detecting whether the voltage below the outage voltage value threshold comprises: drawing power from the capacitor during the instance of the outage time range requirement.

Example 14. The device of any one of Examples 9-13 further comprising: initiating a power saving operational mode for the power outage determination device during the instance of the outage time range requirement.

Example 15. The device of any one of Examples 9-14, further comprising: powering the power outage determination device in a boot cycle after the power outage event; and issuing an alert placeholder comprising a placeholder time since boot value, via the power outage determination device, indicating that the power has been restored.

Example 16. The device of any one of Examples 9-15, further comprising: identifying a timestamp value based on a current time; and correcting the alert placeholder by subtracting a difference between a current time since boot value and the placeholder time since boot value from the current time.

Example 17. A power outage determination device comprising: a sensor adapted to monitor an operational status of electrically powered equipment; a processor adapted to perform operations of: initiating an instance of an outage time range requirement based upon detecting a first voltage value of the power outage determination device below an outage voltage value threshold; monitoring during the instance of an outage time range requirement whether the voltage of the power outage determination device (i) stays below or (ii) returns above the outage voltage value threshold; upon detecting the voltage staying below the outage voltage value threshold during an entirety of the instance of the outage time range requirement, detecting an occurrence of a power outage event; upon detecting the voltage returning above the outage voltage value threshold before termination of the instance of the outage time range requirement: monitoring whether the voltage stays above the outage voltage value threshold during an instance of an interruption time range requirement, the instance of the interruption time range requirement initiated at a time the voltage initially returns above the outage voltage value threshold; and detecting an occurrence of an interruption event based upon the voltage of the power outage determination device staying above the outage voltage value threshold during an entirety of the instance of the interruption time range requirement.

Example 18. The power outage determination device of Example 17, wherein the power outage determination device and the electrically powered equipment both receive power from a same power source.

Example 19. The power outage determination device of any one of Examples 17-18, wherein detecting an occurrence of a power outage event comprises: generating data indicating a power outage occurring at the electrically powered equipment.

Example 20. The power outage determination device of any one of Examples 17-19, wherein the power outage determination device is coupled to a capacitor charging circuit; and
wherein detecting whether the voltage below the outage voltage value threshold comprises:
drawing power from the capacitor during the instance of the outage time range requirement.

Example 21. The power outage determination device of any one of Examples 17-20, further comprising: initiating a power saving operational mode for the power outage determination device during the instance of the outage time range requirement.

Example 22. A power outage determination device comprising: a power monitoring circuit adapted to continuously monitor a voltage range an input voltage of a power source; a processor adapted to determine the occurrence of a power outage event of the power source where the input voltage range falls below a predetermined voltage threshold for a period of time; and a capacitor charging circuit adapted to provide power to the power outage determination device when the voltage range falls below the predetermined voltage threshold.

Example 23. The power outage determination device of Example 22, wherein the device does not include a battery source to provide power to the power outage determination device.

Example 24. The power outage determination device of any one of Examples 22-23, wherein the processor is adapted to determine the occurrence of a power outage event by: initiating an instance of an outage time range requirement based upon detecting a first voltage value of the power outage determination device below an outage voltage value threshold; monitoring during the instance of an outage time range requirement whether the voltage of the power outage determination device (i) stays below or (ii) returns above the outage voltage value threshold; and detecting an occurrence of a power outage event based upon the voltage staying below the outage voltage value threshold during an entirety of the instance of the outage time range requirement.

Example 25. The power outage determination device of Example 22, configured to perform any one of the methods of Examples 1-7.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “identifying” or “determining” or “executing” or “performing” or “collecting” or “creating” or “sending” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may comprise a general purpose computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

Various general purpose systems may be used with programs in accordance with the teachings herein, or it may prove convenient to construct a more specialized apparatus to perform the method. The structure for a variety of these systems will appear as set forth in the description above. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. The disclosure and drawings are, accordingly, to be regarded in an illustrative sense rather than a restrictive sense.

It should be noted that some of the system features described in this specification have been presented as modules to more particularly emphasize their implementation independence. For example, a module may be implemented as a hardware circuit comprising custom very-large-scale integration (VLSI) circuits or gate arrays, off-the-shelf semiconductors such as logic chips, transistors, or other discrete components. A module may also be implemented in programmable hardware devices such as field-programmable gate arrays, programmable array logic, programmable logic devices, graphics processing units, or the like.

A module may also be at least partially implemented in software for execution by various types of processors. An identified unit of executable code may, for instance, comprise one or more physical or logical blocks of computer instructions that may, for instance, be organized as an object, procedure, or function. Nevertheless, the executables of an identified module need not be physically located together but may comprise disparate instructions stored in different locations that, when joined logically together, comprise the module and achieve the stated purpose for the module. Further, modules may be stored on a computer-readable medium, which may be, for instance, a hard disk drive, flash device, random access memory (RAM), tape, or any other such medium used to store data.

Indeed, a module of executable code could be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations, including over different storage devices, and may exist, at least partially, merely as electronic signals on a system or network.

It will be readily understood that the components of the application, as generally described and illustrated in the figures herein, may be arranged and designed in a wide variety of different configurations. Thus, the detailed description of the embodiments is not intended to limit the scope of the application as claimed but is merely representative of selected embodiments of the application.

One having ordinary skill in the art will readily understand that the above may be practiced with steps in a different order and/or with hardware elements in configurations that are different from those which are disclosed. Therefore, although the application has been described based upon these preferred embodiments, it would be apparent to those of skill in the art that certain modifications, variations, and alternative constructions would be apparent.

While preferred embodiments of the present application have been described, it is to be understood that the embodiments described are illustrative only and the scope of the application is to be defined solely by the appended claims when considered with a full range of equivalents and modifications (e.g., protocols, hardware devices, software platforms etc.) thereto.

What is claimed is:

1. A method comprising:
initiating, by a power outage determination device, an instance of an outage time range requirement based upon the power outage determination device detecting a first voltage value of the power outage determination device below an outage voltage value threshold;
monitoring during the instance of an outage time range requirement, by the power outage determination device, whether the voltage of the power outage determination device (i) stays below or (ii) returns above the outage voltage value threshold; and
detecting, by the power outage determination device, an occurrence of a power outage event based upon the voltage staying below the outage voltage value threshold during an entirety of the instance of the outage time range requirement.

2. The method of claim 1, comprising
upon the power outage determination device detecting the voltage returning above the outage voltage value threshold before termination of the instance of the outage time range requirement:
monitoring, by the power outage determination device, whether the voltage stays above the outage voltage value threshold during an instance of an interruption time range requirement, the instance of the interruption time range requirement initiated at a time the voltage initially returns above the outage voltage value threshold; and
detecting, by the power outage determination device, an occurrence of an interruption event based upon the voltage of the power outage determination device staying above the outage voltage value threshold during an entirety of the instance of the interruption time range requirement.

3. The method of claim 1, wherein the power outage determination device is connected to, and monitoring an operational status of, electrically powered equipment; and
wherein the power outage determination device and the electrically powered equipment both receive power from a same power source.

4. The method of claim 3, wherein detecting an occurrence of a power outage event comprises:
generating data, by the power outage determination device, indicating a power outage occurring at the electrically powered equipment.

5. The method of claim 3, wherein the power outage determination device is coupled to a capacitor charging circuit; and
wherein detecting whether the voltage below the outage voltage value threshold comprises:
drawing power from the capacitor, by the power outage determination device, during the instance of the outage time range requirement.

6. The method of claim 1, further comprising:
initiating, by the power outage determination device, a power saving operational mode for the power outage determination device during the instance of the outage time range requirement.

7. The method of claim 1, further comprising:
powering the power outage determination device in a boot cycle after the power outage event; and
issuing an alert placeholder comprising a placeholder time since boot value, via the power outage determination device, indicating that the power has been restored.

8. The method of claim 7, further comprising:
identifying, via the power outage determination device, a timestamp value based on a current time; and
correcting the alert placeholder by subtracting a difference between a current time since boot value and the placeholder time since boot value from the current time.

9. A power outage determination device comprising:
a processor of the power outage determination device adapted to perform operations of:
initiating an instance of an outage time range requirement based upon detecting a first voltage value of the power outage determination device below an outage voltage value threshold;
monitoring during the instance of an outage time range requirement whether the voltage of the power outage determination device (i) stays below or (ii) returns above the outage voltage value threshold; and
detecting an occurrence of a power outage event based upon the voltage staying below the outage voltage value threshold during an entirety of the instance of the outage time range requirement.

10. The device of claim 9, further comprising:
upon detecting the voltage returning above the outage voltage value threshold before termination of the instance of the outage time range requirement:
monitoring whether the voltage stays above the outage voltage value threshold during an instance of an interruption time range requirement, the instance of the interruption time range requirement initiated at a time the voltage initially returns above the outage voltage value threshold; and
detecting an occurrence of an interruption event based upon the voltage of the power outage determination device staying above the outage voltage value threshold during an entirety of the instance of the interruption time range requirement.

11. The device of claim 9, wherein the power outage determination device is connected to, and monitors an operational status of, electrically powered equipment; and
wherein the power outage determination device and the electrically powered equipment both receive power from a same power source.

12. The device of claim 11, wherein detecting an occurrence of a power outage event comprises:
generating data indicating a power outage occurring at the electrically powered equipment.

13. The device of claim 11, wherein the power outage determination device is coupled to a capacitor charging circuit; and
wherein detecting whether the voltage below the outage voltage value threshold comprises: drawing power from the capacitor during the instance of the outage time range requirement.

14. The device of claim 9, further comprising:
initiating a power saving operational mode for the power outage determination device during the instance of the outage time range requirement.

15. The device of claim 9, further comprising:
powering the power outage determination device in a boot cycle after the power outage event; and
issuing an alert placeholder comprising a placeholder time since boot value, via the power outage determination device, indicating that the power has been restored.

16. The device of claim 15, further comprising:
identifying a timestamp value based on a current time; and
correcting the alert placeholder by subtracting a difference between a current time since boot value and the placeholder time since boot value from the current time.

17. A power outage determination device comprising:
a sensor adapted to monitor an operational status of electrically powered equipment;
a processor adapted to perform operations of:
initiating an instance of an outage time range requirement based upon detecting a first voltage value of the power outage determination device below an outage voltage value threshold;
monitoring during the instance of an outage time range requirement whether the voltage of the power outage determination device (i) stays below or (ii) returns above the outage voltage value threshold;
upon detecting the voltage staying below the outage voltage value threshold during an entirety of the instance of the outage time range requirement, detecting an occurrence of a power outage event;
upon detecting the voltage returning above the outage voltage value threshold before termination of the instance of the outage time range requirement:
monitoring whether the voltage stays above the outage voltage value threshold during an instance of an interruption time range requirement, the instance of the interruption time range requirement initiated at a time the voltage initially returns above the outage voltage value threshold; and
detecting an occurrence of an interruption event based upon the voltage of the power outage determination device staying above the outage voltage value threshold during an entirety of the instance of the interruption time range requirement.

18. The power outage determination device of claim 17, wherein the power outage determination device and the electrically powered equipment both receive power from a same power source.

19. The power outage determination device of claim 18, wherein detecting an occurrence of a power outage event comprises:
generating data indicating a power outage occurring at the electrically powered equipment.

20. The power outage determination device of claim 19, wherein the power outage determination device is coupled to a capacitor charging circuit; and
wherein detecting whether the voltage below the outage voltage value threshold comprises:
drawing power from the capacitor during the instance of the outage time range requirement.

21. The power outage determination device of claim 20, further comprising:
initiating a power saving operational mode for the power outage determination device during the instance of the outage time range requirement.

22. A power outage determination device comprising:
a power monitoring circuit adapted to continuously monitor a voltage range of an input voltage of a power source;
a processor adapted to determine the occurrence of a power outage event of the power source where the input voltage range falls below a predetermined voltage threshold for a period of time; and
a capacitor charging circuit adapted to provide power to the power outage determination device when the voltage range falls below the predetermined voltage threshold.

23. The power outage determination device of claim 22, wherein the device does not include a battery source to provide power to the power outage determination device.

24. The power outage determination device of claim 22, wherein the processor is adapted to determine the occurrence of a power outage event by:
initiating an instance of an outage time range requirement based upon detecting a first voltage value of the power outage determination device below an outage voltage value threshold;
monitoring during the instance of an outage time range requirement whether the voltage of the power outage determination device (i) stays below or (ii) returns above the outage voltage value threshold; and
detecting an occurrence of a power outage event based upon the voltage staying below the outage voltage value threshold during an entirety of the instance of the outage time range requirement.
